(19) United States
(12) Patent Application Publication
(10) Pub. No.: US 2007/0160230 A1
(43) Pub. Date: Jul. 12, 2007

(54) Device and method for determining sound source direction

(75) Inventor: Kouichi Nakagomi, Tokorozawa-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 11/651,682

(22) Filed: Jan. 10, 2007

(30) Foreign Application Priority Data
Jan. 10, 2006 (JP) 2006-002284

(51) Int. Cl. H04R 1/40; H03G 9/00

(52) U.S. Cl. 381/97; 381/102; 381/92

(57) ABSTRACT

A sound source direction determining device for specifying the incoming direction of a sound based on acoustic signals through two channels obtained by two mikes disposed apart by a predetermined distance has a phase difference spectrum signal generating unit for obtaining the phase difference spectrum of the acoustic signals through the two channels, a power spectrum signal generating unit for obtaining the power spectrum of at least either one of the acoustic signals through the two channels, and a sound source direction specifying unit for obtaining the sound source direction of each sound source based on the phase difference spectrum and the power spectrum.

### BACKGROUND OF THE INVENTION

1. Field of the Invention

The present invention relates to a device and method for determining the direction of a sound source, by using at least two sensors.

2. Description of the Related Art

Unexamined Japanese Patent Application KOKAI Publication No. 2003-337164 discloses a sound incoming direction detecting method for specifying the incoming direction of a sound based on acoustic signals through two channels, which are detected by two sensors disposed apart from each other by a predetermined distance. This prior art method includes a step of obtaining the spectrum of the phase difference between the acoustic signals through the two channels, and a step of approximating all or a part of the phase difference spectrum obtained at the prior step with a linear function about frequency, which runs on the origin, and calculating the direction of the sound source from the slope of the linear function.

FIGS. 11 to 13 are conceptual diagrams of the prior art. FIG. 11 is a diagram showing the positions of two mikes and the position of a sound source. FIG. 12 is a diagram showing the phase difference spectrum of the acoustic signals that are obtained at the two mikes. FIG. 13 is a diagram showing the correspondence between the sound source direction and the phase difference spectrum.

As shown in FIG. 11, the two mikes 1a and 1b are disposed on the x axis apart from each other by a distance S. The disposing position of one mike 1a is a point A. The disposing position of the other mike 1b is a point B. The point at an equidistance S/2 from both the mikes 1a and 1b is a mid point C. The y axis is drawn to orthogonally cross the x axis at this mid point C. An angle formed by a line segment that extends from the mid point C to the sound source (speaker) 3 and the y axis is θ.

A length parallel with the y axis, which extends from the x axis to the sound source 3, is D. A length parallel with the x axis, which extends from the y axis to the sound source 3, is Δx. The point at which the sound source 3 is positioned is a point E. A circle is drawn to have a center at the point (point E) at which the sound source 3 is positioned, and to have a radius equal to the length from the point E to the point (point B) at which the mike 1b is positioned. The point at which the circle and a line segment from the sound source 3 to the mike 1a intersect each other is F. The distance from this intersection F to the mike 1a is a path difference Δd.

The phase difference between the acoustic signals obtained at the two mikes 1a and 1b is Δφ. Δφ is expressed by the following equation (1).
Δφ=(Δd/c)*f*360 (deg.) (1)
where c represents sound velocity and f represents frequency.

When both sides of the equation (1) are differentiated with respect to the frequency f, an equation
α={d(Δφ)/df}=(Δd/c)*360 (2)
is derived. α in the left side of the equation (2) is dependent on the path difference Δd, i.e., dependent on the direction of the sound. In a case where the path difference Δd is constant, a takes a constant value.

In a case where a sound comes from a specific direction, the frequency dependency of the phase difference Δφ appears as a linear function about frequency, as shown in FIG. 12. In FIG. 12, the horizontal axis represents frequency f and the vertical axis represents phase difference Δφ.

As obvious from the equation (2), the slope α of the linear function is determined by the path difference Δd and the sound velocity c (constant). Accordingly, the slope α of the linear function should change as represented by the equation (2), according to the incoming direction of the sound.

FIG. 13 shows the dependency of the slope α on the angle θ. In FIG. 13, the horizontal axis represents frequency [Hz] and the vertical axis represents phase difference Δφ [degree]. FIG. 13 represents the slope α at some representative angles, for example, θ=−40 [deg.], θ=−20 [deg.], and θ=−10 [deg.]. FIG. 13 plots the graphs according to a rule that a phase difference Δφ of +180 [deg.] is equal to a phase difference Δφ of −180 [deg.]. This is for the sake of plotting.

In a case where the frequency of a sound is zero, the phase difference is also zero. Hence, the linear functions run on the origin (the point at which the frequency is zero and the phase difference is zero). As shown in FIG. 13, as the absolute value of the angle θ increases, the absolute value of the slope α increases.

The direction of the sound source 3 and the slope α of the linear function are in one-to-one correspondence with each other. Accordingly, by approximating the frequency dependency of a measured phase difference Δφ with a linear function and calculating the slope α of the linear function, it is possible to determine the direction of the sound source 3.

Here, when the equation (2) is transformed, the path difference Δd will be
Δd=αc/360 (3).

The path difference Δd can be calculated according to the equation (3). Then, the direction of the sound source 3 can be geometrically calculated from the path difference Δd.

According to the above-described prior art, it is possible to specify the incoming direction of a sound, based on acoustic signals through two channels, which are caught by two mikes disposed apart by a predetermined distance.

However, the above-described prior art has a problem. That is, in a case where sounds come from a plurality of directions, i.e., in a case where there exist a plurality of sound sources, the incoming directions of the sounds from the respective sources cannot be determined.

As a measure for this problem, the above-indicated Unexamined Japanese Patent Application KOKAI Publication No. 2003-337164 describes its “second invention (paragraphs [0074] to [0103])” as follows. That is, the description there reads, “All possible sound source directions that can be estimated based on the spectrum of the phase difference between acoustic signals through the two channels, are calculated. Then, the frequency characteristics of the directions that are estimated as the possible sound source directions are obtained. Then, a linear portion that is parallel with the frequency scale is extracted from the frequency characteristics of the directions that are estimated as the possible sound source directions. In this manner, the directions of a plurality of sound sources can be specified”. However, this measure is based on the premise that the frequency ranges of the plurality of sound sources are clearly different. This measure is poor in the estimation accuracy, if it is used for estimating the directions of a plurality of sound sources which have frequency components in similar ranges.

The above-indicated publication reads as follows. “Sound sources, one of which is ‘a high-frequency speaker 3a having an amplification characteristic like a mountain having a peak at about 5 KHz and having gentle slopes at both sides of 5 KHz’, and the other of which is ‘a low-frequency speaker 3b having an amplification characteristic which has a peak at a low frequency and shows a sharp attenuation toward higher frequency levels to show a sound pressure level of almost 0 at 10 KHz’, are prepared. Even when these sound sources (high-frequency speaker 3a and low-frequency speaker 3b) are driven simultaneously, it is possible to estimate the directions of these sound sources”. Meanwhile, a case in which such a premise is not established is when the sound sources are the voices (sounds) of a plurality of persons, not the above-described sound sources (high-frequency speaker 3a and low-frequency speaker 3b). In this case, the voices (sounds) of the plurality of persons have sexual differences and vocal print differences. However, in terms of frequency ranges, the differences between the voices (sounds) of the plurality of persons are smaller than the difference between the above-described speakers (high-frequency speaker 3a and low-frequency speaker 3b). That is, in such a case, the prerequisite (the frequencies of a plurality of sound sources must be clearly different from each other in order that the directions of these sound sources can be determined) of the above-described prior art is not established. Hence, the prior art has a problem that it cannot achieve a sufficient accuracy in determining the directions of a plurality of sound sources such as the voices (sounds) of a plurality of persons.

### SUMMARY OF THE INVENTION

The present invention was made in view of the above-described circumstances. An object of the present invention is to provide a device and method for determining a sound source direction, which enable determination of the directions of a plurality of similar sound sources, such as voices (sounds) of a plurality of persons.

A sound source direction determining device according to a first aspect of the present invention is a sound source direction determining device for specifying the incoming direction of a sound based on acoustic signals through two channels obtained by two sensors disposed apart from each other by a predetermined distance. The sound source direction determining device comprises: a phase difference spectrum generating unit which obtains a phase difference spectrum of the acoustic signals through the two channels; a power spectrum generating unit which obtains a power spectrum of at least either one of the acoustic signals through the two channels; and a sound source direction specifying unit which obtains a sound source direction of each sound source, based on the phase difference spectrum and the power spectrum.

A sound source direction determining method according to a second aspect of the present invention is a sound source direction determining method for specifying the incoming direction of a sound based on acoustic signals through two channels obtained by two sensors disposed apart from each other by a predetermined distance. The sound source direction determining method comprises: a first step of obtaining a phase difference spectrum of the acoustic signals through the two channels; a second step of obtaining a power spectrum of at least either one of the acoustic signals through the two channels; and a third step of obtaining a sound source direction of each sound source, based on the phase difference spectrum and the power spectrum.

A computer-readable recording medium according to a third aspect of the present invention is a computer-readable recording medium storing a program for controlling a computer to perform sound source direction determination for specifying the incoming direction of a sound based on acoustic signals through two channels obtained by two sensors disposed apart from each other by a predetermined distance. The sound source direction determination comprises: a first step of obtaining a phase difference spectrum of the acoustic signals through the two channels; a second step of obtaining a power spectrum of at least either one of the acoustic signals through the two channels; and a third step of obtaining a sound source direction of each sound source based on the phase difference spectrum and the power spectrum.

### BRIEF DESCRIPTION OF THE DRAWINGS

These objects and other objects and advantages of the present invention will become more apparent upon reading of the following detailed description and the accompanying drawings in which:

FIG. 1A is a conceptual structure diagram of a sound source direction determining device 10 according to a first embodiment, and FIG. 1B is a conceptual structure diagram of a sound source direction determining unit 17;

FIG. 2 is a diagram showing a positional relationship among a plurality of sound sources (a first sound source 18 and a second sound source 19, for expediency) and two mikes (a first mike 11 and a second mike 12);

FIG. 3A is a diagram showing a power spectrum signal S6, and FIG. 3B is a diagram showing a phase difference spectrum signal S5;

FIG. 4 is a conceptual diagram of phase difference spectrum component separation;

FIG. 5 is a structure diagram of a second embodiment;

FIG. 6 is an experimental pattern diagram according to the second embodiment;

FIG. 7 is a diagram showing the result of the experiment;

FIG. 8 a conceptual diagram for explaining Pfor[f], which takes into consideration formant fluctuation of a harmonic structure;

FIG. 9 is a structure diagram of a third embodiment;

FIG. 10 is a diagram showing the disposition of a plurality of sound sources;

FIG. 11 is a diagram showing a positional relationship among two mikes and a sound source;

FIG. 12 is a diagram showing a phase difference spectrum of acoustic signals obtained from two mikes; and

FIG. 13 is a diagram showing a correspondence relationship between sound source direction and phase difference spectrum.

### DETAILED DESCRIPTION OF THE PREFERRED EMBODIMENTS

The first embodiment of the present invention will be explained below with reference to the drawings.

### The First Embodiment

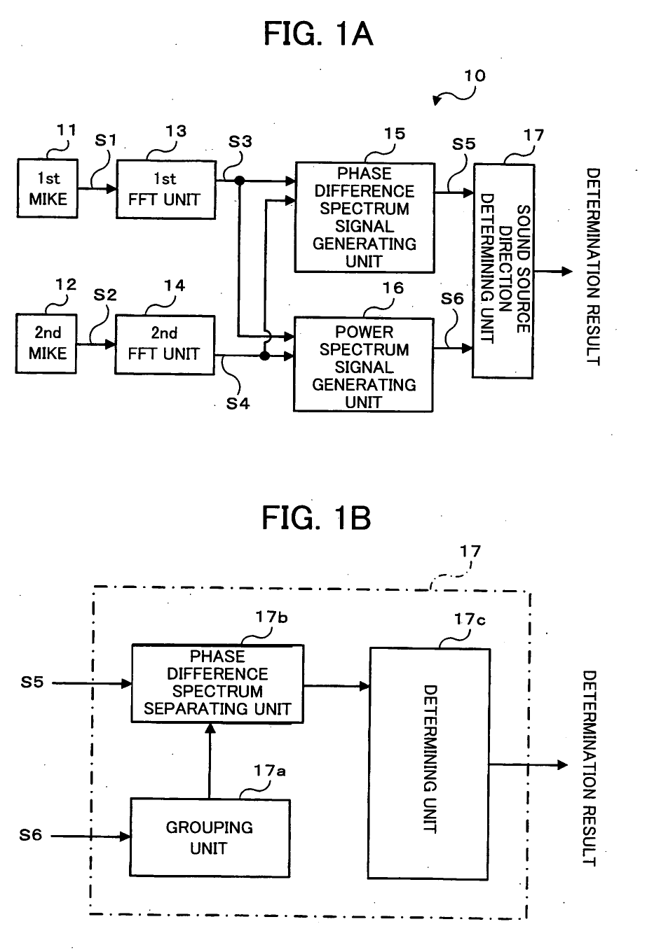

FIG. 1A is a conceptual structure diagram of a sound source direction determining device according to the first embodiment.

As shown in FIG. 1A, the sound source direction determining device 10 comprises two mikes (first mike 11 and second mike 12) for detecting a sound and converting it into an electric signal (hereinafter referred to as acoustic signal). The first mike 11 and the second mike 12 have a constant sensitivity throughout a wide frequency range that varies from low levels to high levels. The first mike 11 and the second mike 12 have omnidirectivity or equal directivity about the direction of a sound source.

The sound source direction determining device 10 comprises two FFT units (first FFT unit 13 and second FFT unit 14). These FFT units 13 and 14 perform fast Fourier transform of two acoustic signals S1 and S2 output from the mikes 11 and 12.

The sound source direction determining device 10 comprises a phase difference spectrum signal generating unit 15. Based on a first FFT signal S3 output from the first FFT unit 13 and a second FFT signal S4 output from the second FFT unit 14, the phase difference spectrum signal generating unit 15 generates a phase difference spectrum signal S5 about the FFT signals S3 and S4.

The sound source direction determining device 10 comprises a power spectrum signal generating unit 16. Based on the first FFT signal S3 output from the first FFT unit 13 and the second FFT signal S4 output from the second FFT unit 14, the power spectrum signal generating unit 16 generates a power spectrum signal S6 about these FFT signals S3 and S4.

The sound source direction determining device 10 comprises a sound source direction determining unit 17. The sound source direction determining unit 17 determines the direction of a sound source (unillustrated) by using the phase difference spectrum signal S5 and the power spectrum signal S6.

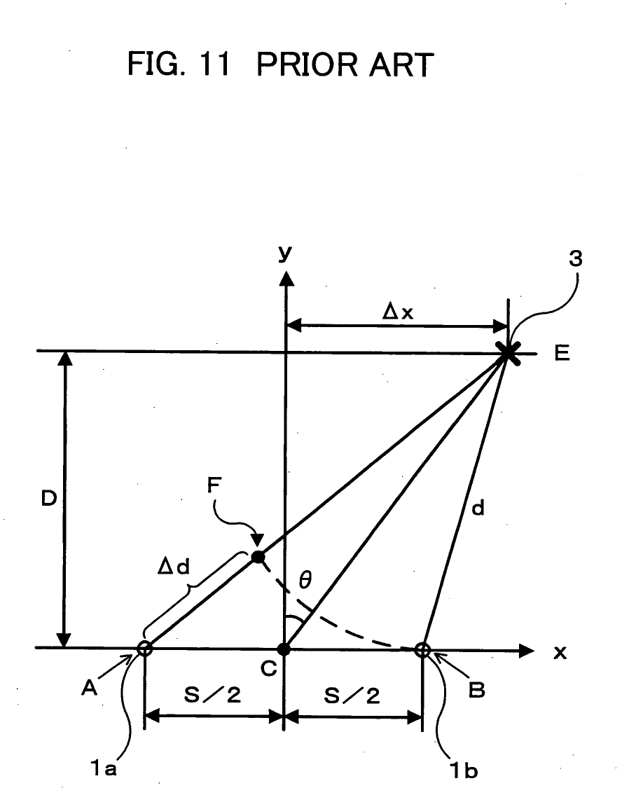

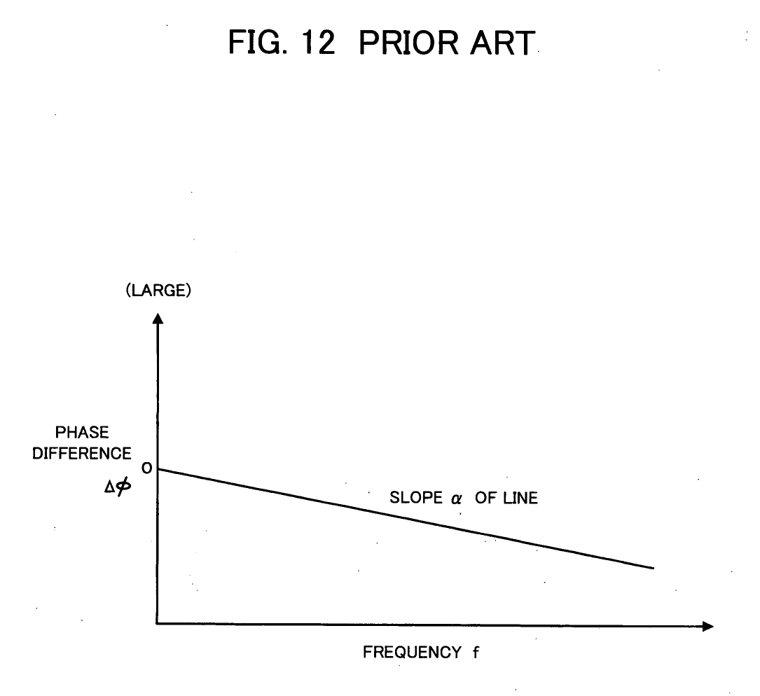

Phase difference spectrum represents frequency dependency of a phase difference between two FFT signals (the first FFT signal S3 and the second FFT signal S4 in the example of FIG. 1A). For example, assume that a sound source, which generates a sound (white noise, for expediency) in a wide frequency range, exists at a point of equidistance (an arbitrary point on the y axis in the example of FIG. 11) from both the first mike 11 and the second mike 12. In this case, the phase difference between the first FFT signal S3 and the second FFT signal S4 is zero all along the frequency scale. Accordingly, in this case, the phase difference spectrum is expressed as a linear function which runs on the origin (frequency f=0, and phase difference Δφ=0) and whose slope α is 0, if explained according to FIG. 12.

Contrarily, consideration will now be given to a case that the sound source is positioned at a point of non-equidistance (for example, the point E in FIG. 11) from the first mike 11 and the second mike 12. In this case, the linear function that expresses the phase difference spectrum runs on the origin, as so in the foregoing case.

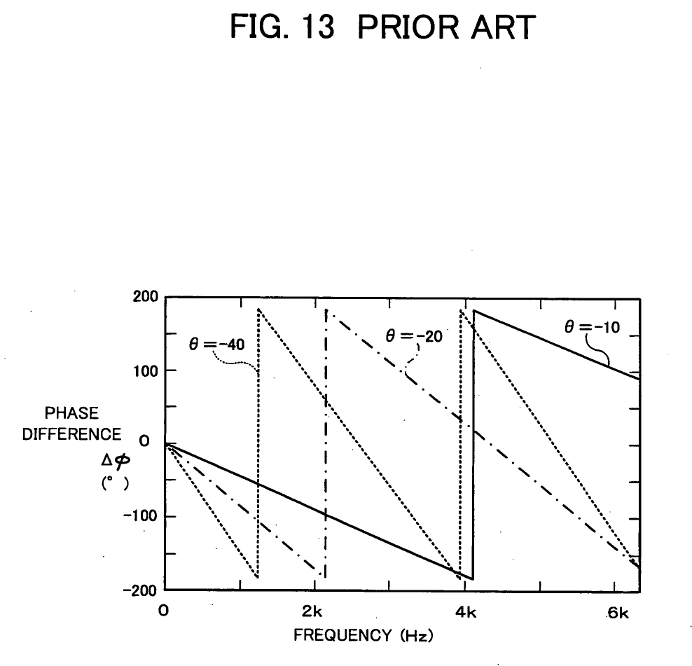

However, the slope α of the linear function is not 0 unlike the foregoing case, but a value that corresponds to the angle θ formed by the line that connects the point E of the sound source and the mid point C between the two mikes, and the y axis. For example, as shown in FIG. 13, in a case where the angle θ is −10 [deg.], the phase difference spectrum is expressed by a linear function having a small slope α, as indicated by the solid line. In a case where the angle θ is −20 [deg.], the phase difference spectrum is expressed by a linear function having a slightly larger slope α, as indicated by the dashed-dotted line. In a case where the angle θ is −40 [deg.], the phase difference spectrum is expressed by a linear function having a further larger slope α, as indicated by the dotted line. In sum, as the angle θ increases, the slope α becomes steeper.

In a case where there is a single sound source, it is possible to determine the direction of the sound source by utilizing the behaviors of such a phase difference spectrum. The above-described angle θ represents the direction of the sound source, and a fixed relationship is established between the angle θ and the slope α of a linear function expressing a phase difference spectrum. Accordingly, by calculating the slope α of the linear function, it is possible to derive the angle θ. That is, it is possible to determine the direction of the sound source.

The above-described matters are also disclosed in the above-indicated publication. The technique disclosed in this publication can also determine the direction (angle θ) of a sound source, as long as this sound source is the only one that is there. However, the technique disclosed in this publication has a drawback that it cannot determine the direction of each of a plurality of sound sources, if the plurality of sound sources generate sounds of similar frequencies. This is because in most cases, a phase difference spectrum originating from a plurality of sound sources does not appear as such a neat line (linear function) as shown in FIG. 12 and FIG. 13, but as a complicated curve that behaves like a noise and changes randomly. As described above, the above-indicated publication states that the technique disclosed therein can determine the directions of a plurality of sound sources, if the source sources have clearly difference frequency ranges. However, this technique cannot determine the directions of a plurality of sound sources, if the sound sources have overlapping frequency regions, such as in case of voices of a plurality of persons. This is because, as described above, in a case where the frequency ranges of a plurality of sound sources overlap with each other, the phase difference spectrum does not appear as a neat line (linear function)), but as a curve that changes randomly like a noise.

In view of such a circumstance, the sound source direction determining device 10 according to the present embodiment utilizes power spectrum in addition to phase difference spectrum. The sound source direction determining device 10 is a device which is enabled to determine the directions of even a plurality of sound sources that have overlapping frequency ranges.

Power spectrum is the intensity (power or signal level) of each frequency component of a signal, which is represented on the frequency scale. A general-purpose measuring instrument called spectrum analyzer is a device for analyzing power spectrum, and can display on its screen a power spectrum where the horizontal axis represents frequency and the vertical axis represents signal intensity at each frequency, when an objective signal of measuring is input to this device.

When a pure single-frequency signal, an ideal sinusoidal signal having a specific frequency for example, is input to the above-described spectrum analyzer, a power spectrum having only one peak that corresponds to the specific frequency is observed. As compared with this, a signal from a sound source such as human voices, music instrumental sounds, chirps of birds, etc. is not a sound that has a single frequency, but a sound that includes various frequency components. Thus, when such a signal is analyzed by the spectrum analyzer, a power spectrum which contains “peaks of the respective frequency components of the signal” is observed.

The “peaks of the respective frequency components of the signal” described above contains a fundamental wave having the lowest frequency and higher harmonic waves whose frequency is an integer multiple of the frequency of the fundamental wave. The higher harmonic waves are called second harmonic wave, third harmonic wave, fourth harmonic wave, . . . , in the order of waves closer to the fundamental wave. This naming is used in alternating current circuit analysis. In the field of music, etc., these waves are also called “fundamental tone” and “overtone”. The fundamental tone (first overtone) is the frequency component that has the lowest frequency among the “peaks of the respective frequency components of the signal”, and the second overtone, the third overtone, the fourth overtone, . . . are the peaks that have a frequency component, which is an integer multiple of the fundamental tone. For example, “do” of a music instrument includes “C3” as the first overtone, “C4” as the second overtone, and “C5” as the fourth overtone. The overtones of “do” also include “E5” and “G5”.

Assume that a first sound source generates a sound “do”, and a second sound source generates a sound “re”. The sound from the first sound source includes a fundamental tone having a frequency of 550.1 Hz, and overtones having frequencies of integer multiples of that frequency (1100.2 Hz, 1650.3 Hz, 2200.4 Hz, . . . ). The sound from the second sound source includes a fundamental tone having a frequency of 623.5 Hz and overtones having frequencies of integer multiples of that frequency (1247.0 Hz, 1870.5 Hz, 2494.0 Hz, . . . ). As obvious from this, by checking the overtone series, it is possible to discriminate which sound source is more influent at a given frequency, even if this frequency is in overlapping frequency ranges.

The sound source direction determining device 10 according to the first embodiment utilizes this principle. The sound source direction determining device 10 is a device which can determine the directions of a plurality of sound sources whose frequency ranges overlap with each other, by utilizing not only phase difference spectrum but also power spectrum.

FIG. 1B is a conceptual structure diagram of the sound source direction determining unit 17. As shown in FIG. 1B, the sound source direction determining unit 17 comprises an overtone grouping unit 17a, a phase difference spectrum separating unit 17b, and a determining unit 17c.

The overtone grouping unit 17a classifies a plurality of peaks included in the power spectrum signal S6 generated by the power spectrum signal generating unit 16 into groups, according to sound sources. This grouping is done as follows, based on a fact that in most cases, each of the plurality of sound sources comprises a fundamental tone and a plurality of overtones as described above, a fact that in most cases, the frequency of the fundamental tone is unique sound-source by sound-source, and a fact that in most cases, the number of overtones and their frequency are not the same between the sound sources. That is, in the grouping process, frequencies that are at constant intervals (pitches), among the plurality of peak frequencies included in the power spectrum signal S6, are classified into one group.

The phase difference spectrum separating unit 17b separates phase difference spectrum components that correspond to the peak frequencies of each group, according to the result of grouping by the overtone grouping unit 17a. The determining unit 17c determines the direction of each group, i.e., the direction of each sound source based on the phase difference spectrum components of each overtone group, that are separated by the phase difference spectrum separating unit 17b, and outputs the determination result.

The operation of the overtone grouping unit 17a, the phase difference spectrum separating unit 17b, and the determining unit 17c will be specifically explained.

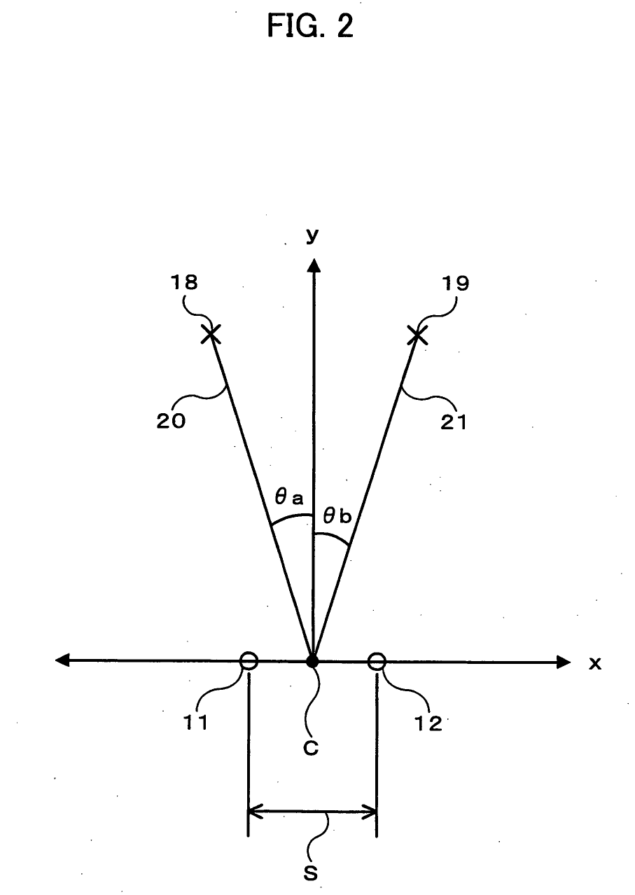

FIG. 2 is a diagram showing the positional relationship among a plurality of sound sources (referred to as first sound source 18 and second sound source 19 for expediency) and two mikes (first mike 11 and second mike 12). The distance between the two mikes (first mike 11 and second mike 12) is S, and the mid point between the two mikes is C. A line that runs on the disposing positions of the two mikes (first mike 11 and second mike 12) is the x axis. A perpendicular line to the x axis at the point C is the y axis. A line 20 is drawn from the first sound source 18 to the mid point C. Also, a line 21 is drawn from the second sound source 19 to the mid point C. The angles formed by these lines 20 and 21 respectively and the y axis are θa and θb.

At such a positional relationship, it is assumed that the first sound source 18 and the second sound source 19 are persons who generate sounds respectively (for facilitating understanding, the first sound source 18 generates a sound “do” and the second sound source 19 generates a sound “re”). At this time, the two mikes (first mike 11 and second mike 12) receive the sounds (“do” and “re”) from the first sound source 18 and the second sound source 19, and output acoustic signals S1 and S2, which are the combinations of these sounds. The first FFT unit 13 and the second FFT unit 14 perform fast Fourier transform of these acoustic signals S1 and S2, respectively, and output FFT signals S3 and S4. The phase difference spectrum signal generating unit 15 generates a phase difference spectrum signal S5 from the FFT signals S3 and S4 and outputs the signal S5. The power spectrum signal generating unit 16 generates a power spectrum signal S6 from the FFT signals S3 and S4 and outputs the signal S6.

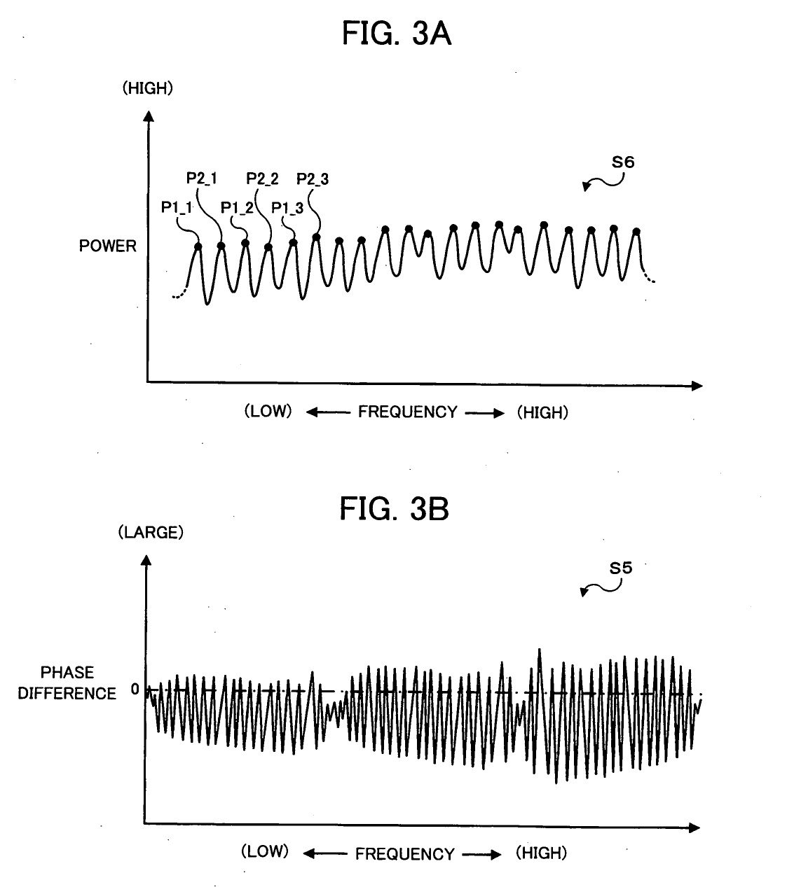

FIGS. 3A and 3B are output signal characteristic diagrams of the output signals from the phase difference spectrum signal generating unit 15 and the power spectrum signal generating unit 16. FIG. 3A is a diagram showing the power spectrum signal S6. FIG. 3B is a diagram showing the phase difference spectrum signal S5.

In FIG. 3A, the vertical axis represents power (signal intensity) and the horizontal axis represents frequency. In FIG. 3B, the vertical axis represents phase difference and the horizontal axis represents frequency. In the example shown here, the phase difference spectrum signal S5 does not appear as a neat line (liner function), unlike in the case of a single sound source. This is because the phase difference spectrum signal S5 is a signal that results from the sound waves from the plurality of sound sources (first sound source 18 and second sound source 19) being superimposed or synthesized. As a reflection of this, the phase difference spectrum signal S5 in the diagram is drawn as a complex spectrum characteristic line that changes randomly with behaviors like a noise. It is impossible to determine the directions of the plurality of sound sources (first sound source 18 and second sound source 19) only from the phase difference spectrum signal S5 having such a spectrum characteristic.

On the other hand, with attention paid to the power spectrum signal S6 in FIG. 3A, this power spectrum signal S6 has a plurality of peaks on the frequency scale. For facilitating understanding, each peak is indicated by a black circle. It is expected that these peaks correspond to the fundamental tone and overtones of the sounds from the plurality of sound sources (first sound source 18 and second sound source 19).

As described above, since the first sound source 18 generates a sound “do” and the second sound source 19 generates a sound “re”, the sounds from the first sound source 18 and the second sound source 19 have different fundamental tones and different overtones from each other. The frequency of the fundamental tone of “do” is 550.1 Hz, and the frequency of the fundamental tone of “re” is 623.5 Hz. Accordingly, the sound from the first sound source 18 includes the fundamental tone having the frequency 550.1 Hz and overtones having frequencies of integer multiples of that frequency (1100.2 Hz, 1650.3 z, 2200.4 Hz, . . . ). Meanwhile, the sound from the second sound source 19 includes the fundamental tone having the frequency 623.5 Hz, and overtones having frequencies of integer multiples of that frequency (1247.0 Hz, 1870.5 Hz, 2494.0 Hz, . . . ).

When the frequencies of these fundamental tones and overtones are organized in the ascending order on the frequency scale, the order will be 550.1 Hz (1), 623.5 Hz (2), 1100.2 Hz (1), 1247.0 Hz (2), 1650.3 Hz (1), 1870.5 Hz (2), 2200.4 Hz (1), 2494.0 Hz (2), . . . The parenthesized numbers indicate the first sound source 18 and the second sound source 19. For example, “550.1 Hz (1)” means that the peak frequency 550.1 Hz is the frequency of the sound from the first sound source 18.

Like this, in the power spectrum signal S6 shown in FIG. 3A, the peaks originating from the first sound source 18 and the peaks originating from the second sound source 19 appear alternately. Hereinafter, the frequency peaks of the first sound source 18 will be represented by symbols P1_1, P1_2, P1_3, P1_4, P1_5, . . . Likewise, the frequency peaks of the second sound source 19 will be represented by symbols P2_1, P2_2, P2_3, P2_4, P2_5, . . .

The “overtone grouping” described above is the operation of separating the peaks of he power spectrum signal S6 into the group of P1_1, P1_2, P_3, P1_4, P1_5, . . . , and into the group of P2_1, P2_2, P2_3, P2_4, P2_5, . . . That is, this operation is for separating the peaks into the first group of P1_, P1_2, P1_3, . . . , and into the second group of P2_1, P2_2, P2_3, . . . To be more specific, according to the above-described example, the first group is the collection of the peak at the frequency 550.1 Hz of the fundamental tone, and peaks that are at the pitches equal to the value of the frequency of the fundamental tone. Likewise, the second group is the collection of the peak at the frequency 623.5 Hz of the fundamental tone, and peaks that are at the pitches equal to the value of the frequency of the fundamental tone.

As described above, the phase difference spectrum separating unit 17b separates the phase difference spectrum components that correspond to the peak frequencies of each group, according to the result of grouping by the overtone grouping unit 17a.

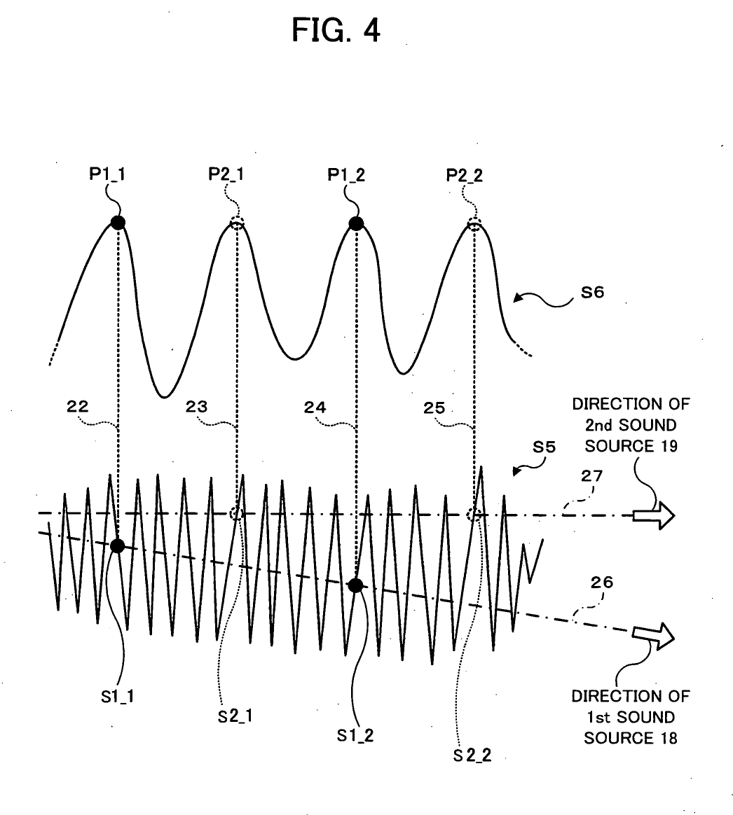

FIG. 4 is a conceptual diagram of phase difference spectrum component separation. In this diagram, the power spectrum signal S6 and the phase difference spectrum signal S5 are plotted on the same frequency scale. The broken lines 22 to 25 that are dropped from the respective peaks (P1_, P2_1, P1_2, P2_2, . . . ) of the power spectrum signal S6 to the phase difference spectrum signal S5 are for indicating the positions at which the phase difference spectrum signal S5 is separated. The components of the phase difference spectrum signal S5 that intersect these broken lines 22 to 25 are the values to be separated. That is, in the example of the diagram, regarding the peak P1_l of the power spectrum signal S6, a component S1_1 of the phase difference spectrum signal S6 that corresponds to this peak frequency is the value to be separated. Likewise, regarding the peak P2_1 of the power spectrum signal S6, a component S2_1 of the phase difference spectrum signal S5 that corresponds to this peak frequency is the value to be separated. Likewise, regarding the peak P1_2 of the power spectrum signal S6, a component S1_2 of the phase difference spectrum signal S5 that corresponds to this peak frequency is the value to be separated. Likewise, regarding the peak P2_2 of the power spectrum signal S6, a component S2_2 of the phase difference spectrum signal S5 that corresponds to this peak frequency is the value to be separated.

As described above, the determining unit 17c determines the sound source directions of the respective overtone groups, i.e., the directions of the first sound source 18 and second sound source 19 based on the phase difference spectrum components (S1_, S2_1, S1_2, S2_2, . . . ) of the respective overtone groups that are separated by the phase difference spectrum separating unit 17b, and outputs the determination results.

The dashed-dotted lines 26 and 27 shown in FIG. 4 are for showing the concept of determination of the directions of the first sound source 18 and second sound source 19, done by the determining unit 17c. One dashed-dotted line 26 connects the phase difference spectrum components (S1_1, S1_2, . . . ) of the first group. The other dashed-dotted line 27 connects the phase difference spectrum components (S2_1, S2_2, . . . ) of the second group.

These dashed-dotted lines 26 and 27 are equivalent to the line(s) (linear function(s)) shown in FIG. 12 and FIG. 13. Accordingly, it is possible to determine the directions of the first sound source 18 and second sound source 19 from the slopes α of these dashed-dotted lines 26 and 27.

As described above, the sound source direction determining device 10 according to the first embodiment determines the sound source direction in consideration of not only the phase difference spectrum but also the power spectrum. Therefore, the sound source direction determining device 10 can correctly determine even the sound source directions of a plurality of sound sources that generate sounds having similar frequency characteristics, such as human voices, music instrumental sounds, etc., needless to say about a single sound source.

In a case where there are a plurality of sound sources that generate a single frequency, the sound from each sound source has no overtones. Therefore, no groups of a plurality of power peaks are to be formed. However, unless the frequencies of the respective sounds completely coincide with each other, it is possible to determine the directions of the plurality of sound sources by referring to the values of the phase difference spectrum that correspond to power peaks. That is, the sound source direction determining device 10 according to the first embodiment can also determine the directions of sound sources that generate sounds having no overtones.

According to the first embodiment, the peaks of the power spectrum are grouped sound-source by sound-source. Next, an embodiment that can determine the sound source directions by separating them from each other without discriminating which peaks of the power spectrum are from which sound sources will be explained.

### The Second Embodiment

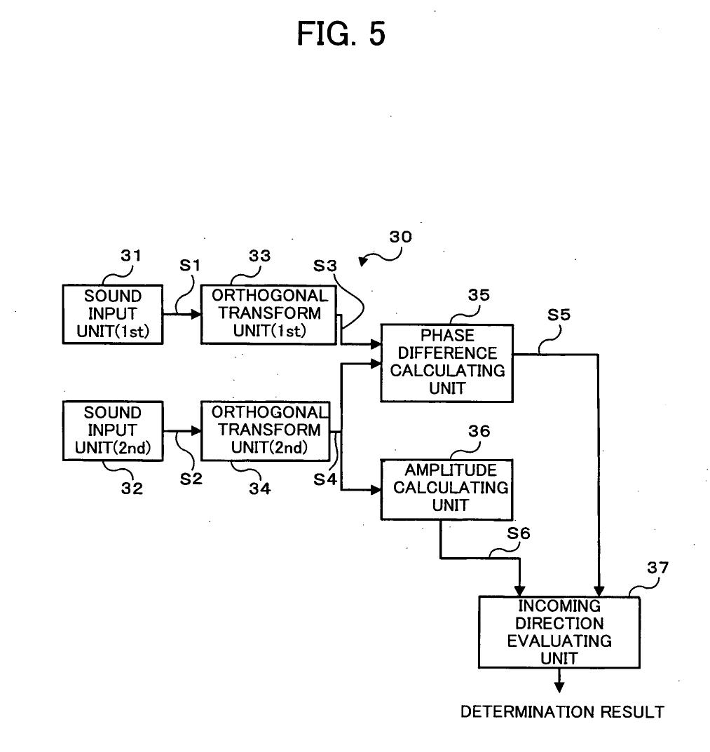

FIG. 5 is a structure diagram of the second embodiment. As shown in FIG. 5, the sound source direction determining device 30 comprises two input units (first sound input unit 31 and second sound input unit 32) each comprising a microphone, an ADC (Analog-Digital Converter), etc. The first sound input unit 31 and the second sound input unit 32 convert sounds from sound sources (unillustrated) into digital acoustic signals S1 and S2, and output them. The acoustic signals S1 and S2 are input to two orthogonal transform units (first orthogonal transform unit 33 and second orthogonal transform unit 34). These two orthogonal transform units (first orthogonal transform unit 33 and second orthogonal transform unit 34) perform orthogonal transform (Fourier transform or the like) of the digitalized acoustic signals S1 and S2 through two channels, to transform them into signals (FFT signals S3 and S4) in the frequency domain. The FFT signals S3 and S4 are input to a phase difference calculating unit 35. The phase difference calculating unit 35 calculates the cross spectrum of the two channels, based on the real part and imaginary part of the two FFT signals S3 and S4 output from the first orthogonal transform unit 33 and the second orthogonal transform unit 34. Then, the phase difference calculating unit 35 obtains a phase difference spectrum signal S5 regarding the two channels based on the cross spectrum. The FFT signal S4 output from one orthogonal transform unit (here, the second orthogonal transform unit 34) is also input to an amplitude calculating unit 36. The amplitude calculating unit 36 calculates a power spectrum signal S6 based on the FFT signal S4 obtained through one of the two channels. The phase difference spectrum signal S5 and power spectrum signal S6 obtained in these manners are input to an incoming direction evaluating unit 37. The incoming direction evaluating unit 37 analyzes the phase difference spectrum signal S5 and power spectrum signal S6 from various aspects. Then, basing on an assumption that the phase difference spectrum curve is a linear function about frequency, evaluating unit 37 evaluates the slopes α of the linear functions and determines the directions of the sound sources based on the slopes α.

As described above, it is known that the direction of a sound source can be estimated from the slope of the graph representing the phase difference of acoustic signals through two channels, that are detected by two mikes.

The two digitalized acoustic signals S1 and S2 output from the first sound input unit 31 and second sound input unit 32 are to be represented by time series digital data x(t) and y(t) respectively, where t represents time.

The first orthogonal transform unit 33 and the second orthogonal transform unit 34 extract a section having a predetermined time length from the time series data x(t) and y(t) input thereto, and multiply the extracted section by a window function (a humming window or the like). The first orthogonal transform unit 33 and the second orthogonal transform unit 34 perform orthogonal transform (FFT or the like) of the window-multiplied section, to obtain coefficients xRe[f], yRe[f], xIm[f], and yIm[f] in the frequency domain, where Re represents real part, Im represents imaginary part, and f represents frequency.

The phase difference calculating unit 35 calculates the real part CrossRe[f] and imaginary part CrossIm[f] of the cross spectrum, by using the following equations.
CrossRe[f]=xRe[f]*yRe[f+xIm[f]*yIm[f] (4)
CrossIm[f]=yRe[f]*xIm[f]−xRe[f]*yIm[f] (5)

The phase difference spectrum C[f] between the signals x(t) and y(t) at a frequency f is derived by the following equation, according to the angle formed by the real part and imaginary part of the cross spectrum.
C[f]={a tan(CrossIm[f]/CrossRe[f])}*(180/π) (6)

The amplitude calculating unit 36 calculates the power spectrum P[f] by the following equation where sqrt represents square root.
P[f]=sqrt(yRe[f]*yRe[f]+yIm[f]*yIm[f]) (7)

The introduction of the power spectrum P(t) has the following meaning. Most sound sources have overtones that are based on the fundamental pitch component. When orthogonal transform such as Fourier transform, etc. is applied to a signal generated by a sound source, a power spectrum in the frequency domain can be obtained. In such a power spectrum, harmonic structure appears which has peaks at frequencies corresponding to constant multiples of the pitch frequency. It can be said that the frequency ranges in which the power is weak (the portions that are no overtones) are ranges in which the influence from the sound sources is small. Likewise, regarding phase difference components, it can be said that the frequency ranges that correspond to the frequency ranges in which the power is weak are ranges in which the influence from the sound sources is small.

Further likewise, in a cross spectrum (representing the phase difference between the frequency components of two sounds) of mike signals of two sounds, it can be said that the frequency ranges in the cross spectrum that correspond to the frequency ranges in which the power is weak receive smaller influence from the sound sources and do not weigh heavily in evaluating approximate linear functions that correspond to specific directions as the sound source directions.

In a case where a plurality of sounds come from different directions, phase differences in the cross spectrum get disordered heavily, and the plotted dots are dispersed. In plotting an approximate function (linear function) at a slope ki (i=1, 2, 3, . . . ) representing the direction of one sound source, it is crucial to draw a fine approximate linear function by selecting effective dots from these dispersed dots. Since power values can be considered as the effectiveness of cross spectrum values, it is appropriate to weight an evaluation value of the approximate function with power values P[f] corresponding to points of a phase difference spectrum C[f] which take values close to the values of the approximate function, in a manner that the evaluation value of the approximate function becomes higher as the power values P[f] correspondings to points in the phase difference spectrum C[f] become higher. With such weighting, the evaluation value will serve as an index indicating to what degree the approximate function is approximate, i.e., an index indicating how appropriately the approximate function reflects that the sound source exists in a specific direction. With the intention of assuming various slopes to decide which slope(s) is(are) appropriate enough among such slopes, it is necessary to use the subscript “i” in the symbol ki to distinguish these slopes from one another.

Sounds generated from different sound sources at different positions seldom have the same pitch frequency, but in many cases have a gap in their pitch frequency, even if the gap is slight. That is, the power spectrum of a signal in which sounds from a plurality of sound sources are synthesized has peaks corresponding to the harmonic structures of the respective sound sources. Meanwhile, the cross spectrum represents the phase difference between two signals at each frequency. Therefore, in a case where here are a plurality of sound sources in different directions, the cross spectrum is dispersed according to these directions.

Assume that there are two sound sources. And assume a approximate linear function at a slope ki representing the direction of one sound source. At power peak frequencies attributed to the harmonic structure of the sound source in that direction, the phase difference spectrum C[f] itself is also plotted on the assumed approximate function. Such plotting is notable in a case where the peaks appear at frequencies that are apart from the peak values of the harmonic structure attributed to the other sound source. Therefore, in evaluating the degree of approximation (the degree of how the approximate function is appropriate in reflecting the existence of the sound source) of the approximate linear function, it is preferable to adopt the following evaluation criterion. That is, it is preferable to adopt an evaluation criterion according to which the approximate function is evaluated advantageously (evaluated with a high value) in a case where the approximate function includes values that are close to cross values C[f], at high power values P[f].

The incoming direction evaluating unit 37 first calculates all possible sound source directions that can be estimated based on the measured phase differences C[f] and power values P[f]. Specifically, the incoming direction evaluating unit 37 calculates the evaluation value Ki of the approximate linear function whose slope is ki, based on the following evaluation function equation (equation (8)). It can be considered that a slope ki which will achieve a high evaluation value Ki is a slope ki which reflects the existence of the sound source the most appropriately.
Ki=P[f0]*{1/(1+|ki*f0−C[f0]|)}+P[f1]*{1/(1+|ki*f1−C[f1]|)}+. . . +P[fn]*{1/(1+|ki*fn−C[fn]|)} (8)

The incoming direction evaluating unit 37 assumes many slopes (k1, k2, k3, . . . ) as the slope ki, in the range of values corresponding to all possible sound source directions that can be estimated. The incoming direction evaluating unit 37 calculates the evaluation value Ki for each slope ki. The absolute value of (ki*f−C[f]) in the right side of the equation (8) indicates the distance between the approximate line at the slope ki and the phase difference C[f], at a given frequency f. Accordingly, the shorter the distance is, the larger the value of the right side is. P[f] in the right side indicates the amplitude at a given frequency f. The smaller the amplitude is, the smaller the value of the right side is. Accordingly, even if the approximate line and the phase difference take close values to each other, the evaluation will be low if the amplitude is small. The result obtained by accumulating this value in the range of frequencies f0 to fn is the evaluation value Ki.

That is, the evaluation value Ki is obtained by taking into consideration weighting by amplitude values, in evaluating the approximate line at the slope ki. It can be said that the larger the Ki value is, the more appropriate the approximate line at the slope ki is as the reflection of the large contribution from a sound source.

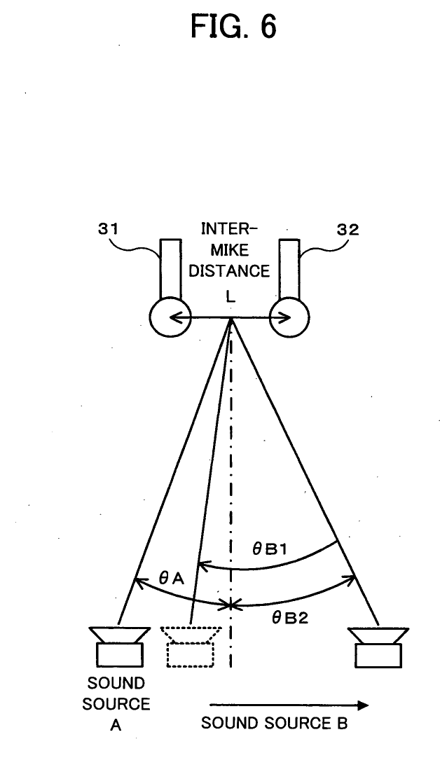

FIG. 6 is an experimental pattern diagram according to the second embodiment. This experimental pattern diagram shows an experiment example carried out under the conditions that the distance (inter-mike distance L) between the first sound input unit 31 and the second sound input unit 32 is 150 mm, the direction θA of a sound source A is fixed at 5 degrees, and a sound source B starts to generate a sound at a timing of 400 milliseconds when it is in a direction θB1, and keeps generating the sound for a period of 1,000 milliseconds while gradually moving to a direction θB2.

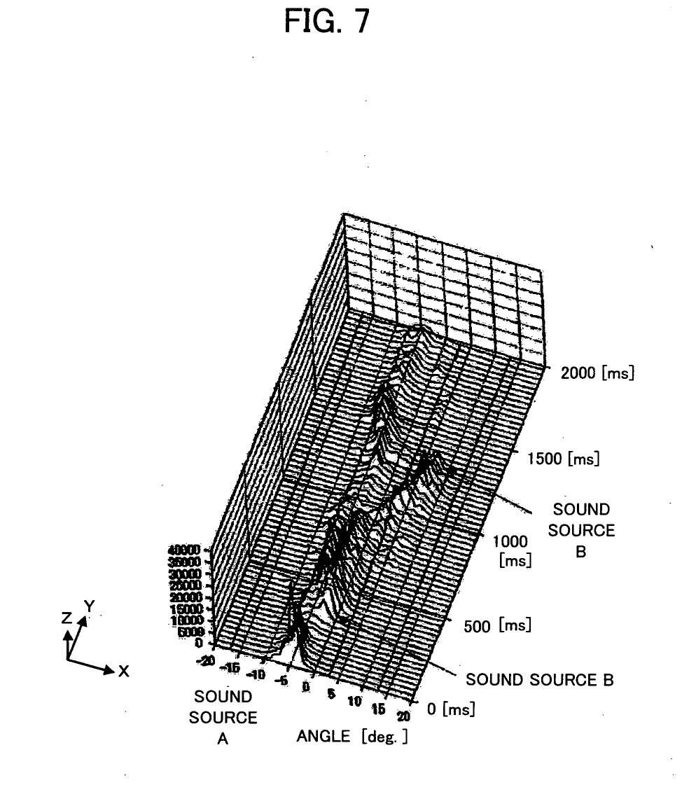

FIG. 7 is a diagram showing the result of the experiment. The calculations were done under the conditions that the humming window is 680 milliseconds, the frequency f0 is 500 Hz, and the frequency fn is 2000 Hz. The X axis represents the value (degree) of incoming angle, which was converted from the value of ki. In this conversion, the inter-mike distance L was 150 mm. The Z axis represents the evaluation value Ki. FIG. 7 plots the X-Z plane on the Y axis while shifting the humming window by each 10 milliseconds.

From the result of the experiment, it can be known that a sound was constantly generated at about 5 degrees on the left. It can also be known from the result of the experiment that another sound source was generated in a time span of about 400 milliseconds to about 1400 milliseconds, and this another sound moved.

As obvious from this, the sound source direction determining device 30 according to the second embodiment can trace the direction of a sound source which moves as time goes.

Further, as obvious from the above, the sound source direction determining device 30 can determined the number of sound sources.

In this experiment, sounds whose frequency is equal to or lower than 500 Hz have a wavelength that is long, when compared with respect to the inter-mike distance (the wavelength of a sound wave whose frequency is 500 Hz is 660 mm). Hence, it is difficult to correctly calculate the phase difference C[f] of the sounds whose frequency is equal to or lower than 500 Hz. Accordingly, the frequency f0, which is the lower frequency limit in the calculations, was set to 500 Hz.

On the other hand, sounds whose frequency is equal to or higher than 2000 Hz have a wavelength that is short, when compared with respect to the inter-mike distance (the wavelength of a sound wave whose frequency is 2000 Hz is 165 mm). Thus, it is difficult to correctly calculate the phase difference C[f] of the sounds whose frequency is equal to or higher than 2000 Hz. Further, in order that the harmonic structure of a sound can sufficiently be expressed by short time FFT, the frequency of the sound needs to be equal to or lower than 3000 Hz. This frequency of 3000 Hz corresponds to the second formant in a human voice. Due to the above-described reason, and with a view to omitting any unnecessary calculations for accelerating the calculation process, the frequency fn, which is the upper frequency limit in the calculations, was set to 2000 Hz.

Next, a first modification example of the second embodiment will be described. The value P[f] in the above-indicated evaluation equation (8) is replaced with a value Pbi[f] in the following equation (9).
Pbi[f]=1 or 0
[1: when P[f]≧Pth is satisfied, 0: when P[f]<Pth is satisfied] (9)

In this case, the phase difference spectrum is accumulated only when the phase difference spectrum value is a value at a frequency at which the power exceeds the threshold Pth. Accordingly, noise components, which have a relatively low power but spread over a wide range, become less influential in the calculation, and the reliability of the evaluation value Ki improves. Meanwhile, since any power values that exceed the threshold Pth are replaced with a constant to express their contribution, power peaks, which occur accidentally, become less influential in the calculation. Therefore, the reliability of the evaluation value Ki improves.

Next, a second modification example of the second embodiment will be described.

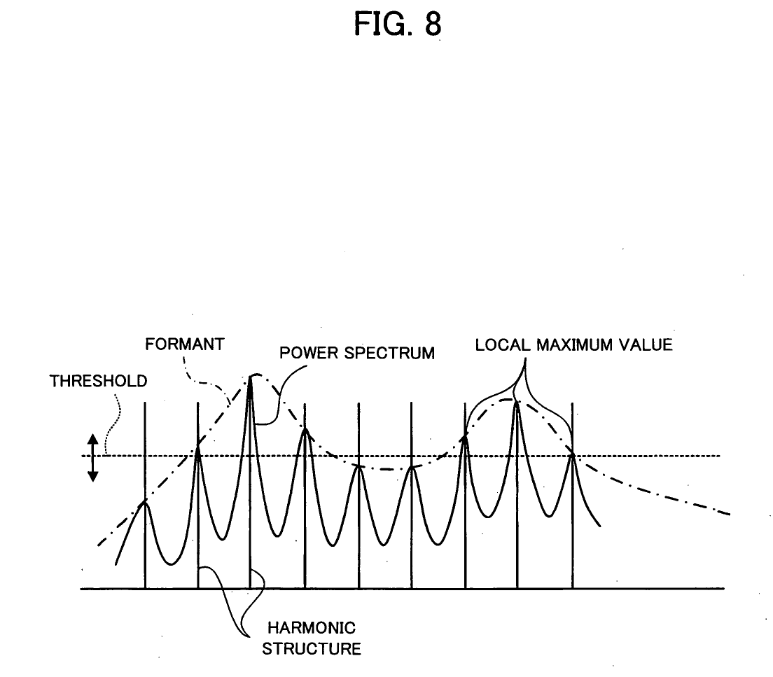

FIG. 8 is a conceptual diagram for explaining the formant fluctuation of a harmonic structure. In a human voice, a generated sound of each kind has its unique formant. Because of this formant, some overtones in the harmonic structure have low power. Therefore, according to the above-described second embodiment, the existence of an overtone having low power is not sufficiently reflected.

In the first modification example of the second embodiment, normalization of a certain kind is adopted. According to this normalization, an overtone having low power is ignored in the calculation of the evaluation value Ki, if the threshold is set too high. On the other hand, if the threshold is set too low, even components other than the overtones (in many cases, unnecessary noises) can give influence on the evaluation value Ki. To prevent these, the value P[f] in the above-indicated evaluation equation (8) is replaced with Pfor[f] shown in the following equation (10).
Pfor[f]=P[f] or 0
[P[f]: when |f-fpk|<fth is satisfied, 0: when |f-fpk|≧fth is satisfied] (10)

The value fpk represents a frequency f, which corresponds to a local maximum value (each peak value) in the power spectrum. By this replacement, it becomes possible to utilize the components from each sound source according to the power of the components, while ignoring noise components.

The above-described second embodiments and its modification functions can be summarized as the following equation (equation (11)).
Ki=Pwr[f0]*Csp[f0]+Pwr[f1]*Csp[1]+. . . +Pwr[fn]*Csp[fn]
where Pwr[f]=P[f] or Pbi[f] or Pfor[f, and Csp[f]=1/(const+|ki*f−C[f]|) (11)

The value Pwr[f] is a function for reflecting the power at each frequency. The value Csp[f is a function that indicates to what degree a linear function ki*f representing the incoming direction of a sound and the phase difference spectrum are close to each other. The value of ki*f−C[f] becomes 0, when the line ki*f is equal to the curve C[f]. The value Csp[f] is the inverse number of this value. Therefore, the value Csp[f] becomes large at a frequency f at which ki*f and C[f] are equal to each other. The value const is a constant for preventing a division by zero. As the value const becomes smaller, the change of the value Csp[f] becomes steeper. It is possible to determine the directions of a plurality of sound sources, by changing the slope ki in the range of values that can be taken by all possible sound source directions that can be estimated (i.e., by assuming various values for ki, like k1, k2, k3, . . . ) to calculate the evaluation value Ki for each slope ki, and by obtaining the peak (local maximum value) of the evaluation value Ki (i.e., by finding out the local maximum value from K1, K2, K3, . . . ).

The evaluation value Ki is the product of Pwr[f], which is a term dependent on the power spectrum, and Csp[f], which is a term dependent on the phase difference spectrum.

### The Third Embodiment

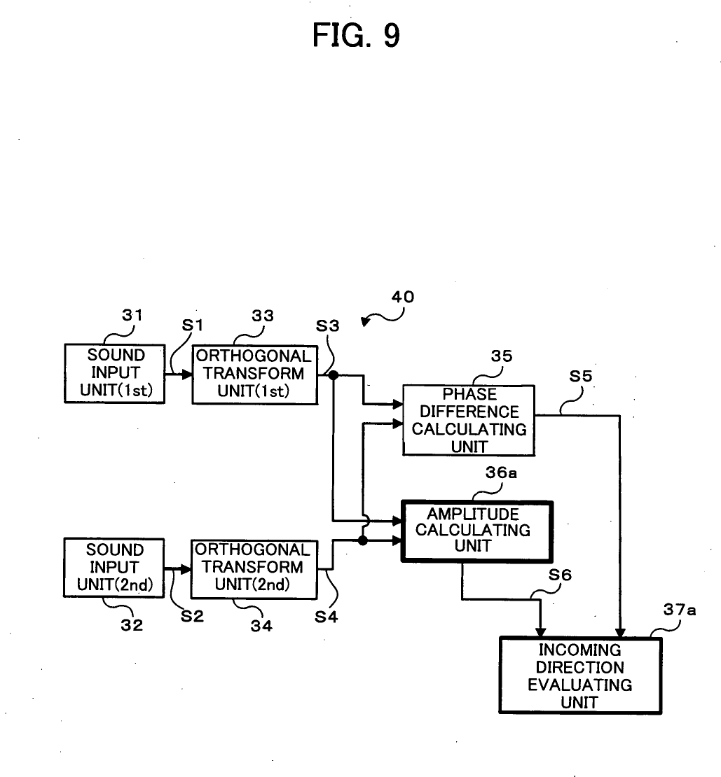

FIG. 9 is a structure diagram of the third embodiment. The sound source direction determining device 40 according to the third embodiment and the sound source direction determining device 30 according to the second embodiment are different in the following two points. First, an amplitude calculating unit 36a of the sound source direction determining unit 40 calculates the amplitude of two channels, based on FFT signals S3 and S4 obtained through the two channels. Second, an incoming direction evaluating unit 37a evaluates the slope by taking into consideration the amplitude of one channel (a power spectrum signal S6 generated from the FFT signal S3) when the slope of the linear function is positive, and taking into consideration the amplitude of the other channel (a power spectrum signal S6 generated from the FFT signal S4) when the slope of the linear function is negative.

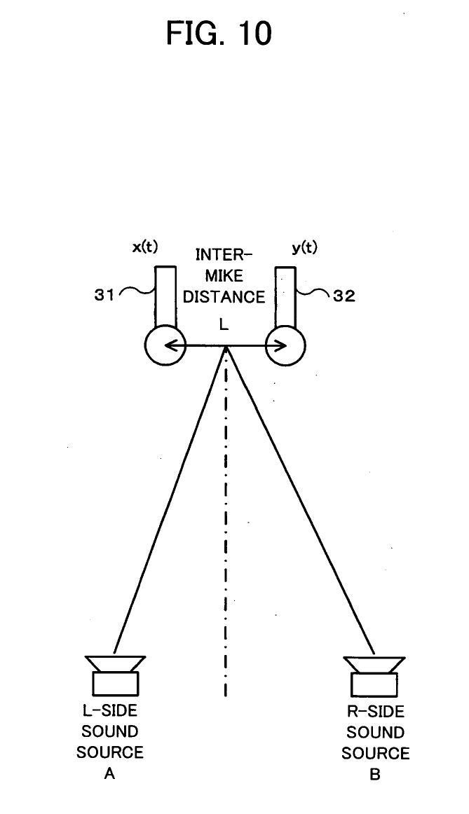

FIG. 10 is a diagram showing the disposition of a plurality of sound sources. As shown in this diagram, a sound source that is located to the left from the center is A, and a sound source that is located to the right is B. Likewise in the second embodiment, when the graphs of frequency-phase difference lines are plotted according to the equations (4) to (6), the slope ki of the left sound source takes a positive value, and the slope ki of the right sound source takes a negative value.

In a case where a sound source is located on the left, a component of the left sound source obtained by the first sound input unit 31 takes a larger value than a component of the left sound source obtained by the second sound input unit 32. This is because the first sound input unit 31 is located more closely to the sound source than the second sound input unit 32 is. The amplitude calculated by the first sound input unit 31 is PL[f], and the amplitude calculated by the second sound input unit 32 is PR[f]. Then, among the components PL[f] and PR[f], the amplitude components that are from the sound source A is in a relationship of PL[f]>PR[f]. Here, PL[f] and PR[f] are given by the following equations.
PL[f]=sqrt(xRe[f]*xRe[f]+xIm[f]*xIm[f]) (12)
PR[f]=sqrt(yRe[f]*yRe[f]+yIm[f]*yIm[f]) (13)

In a case where the slope ki is a positive value, the amplitude PL[f] obtained by the first sound input unit 31 is used as the amplitude P[f] in the above-indicated evaluation equation (equation (8)). In a case where the slope ki is a negative value, the amplitude PR[f] obtained by the second sound input unit 32 is used as the amplitude P[f] in the above-described evaluation equation (equation (8)).

According to the third embodiment, in calculating the evaluation value Ki, the amplitude, which is obtained from a mike (the first sound input unit 31 or the second sound input unit 32) that is closer to each sound source component, is used. As a result, the sound source direction determining device 40 according to the third embodiment also has an IDD (Interaural Intensity Difference) effect, which determines the direction of the sound source, which generates a louder sound, as the incoming direction.

The sound source direction determining device according to the above-described embodiments needs not be a special-purpose device for sound source direction determination. For example, it is also possible to construct hardware by connecting stereo mikes to mike input portions of a computer apparatus, installing a program for controlling the computer apparatus to work as the above-described sound source direction determining device on the computer apparatus from a computer-readable recording medium storing the program, and executing the program on the computer apparatus, thereby to control the computer apparatus to operate as the above-described sound source direction determining device.

It is apparent that the specifications and exemplifications of various details and the designations of numerals, characters and other symbols are for illustration purposes only, for clarifying the idea of the present invention, and the idea of the present invention is not limited by all or some of them. Further, though detailed explanations for known methods, known processes, known architectures, and known circuit layouts, etc. (hereinafter referred to as “known matters”) have been omitted, this is for simplifying the explanation but not to intentionally exclude all or some of these known matters. Since these known matters are available to those having ordinary skill in the art when the application for the present invention is filed, they are naturally included in the explanation.

According to the present invention, the phase difference spectrum of acoustic signals through two channels is generated. At the same time, according to the present invention, the power spectrum of both or one of the acoustic signals through the two channels is generated. Based on the phase difference spectrum and power spectrum generated in this manner, the sound source direction (the direction in which a sound comes transmitted) of each sound source is determined. According to a preferred embodiment, contributing components of each sound source, that are to contribute to the determination, are discriminated from among the phase difference spectrum components, based on the power spectrum. Based on this discrimination, the incoming direction of each sound source is determined. According to another preferred embodiment, contributing components of each sound source, that are to contribute to the determination, are discriminated from among the phase difference spectrum components, based on a term dependent on the power spectrum and a term dependent on the phase difference spectrum. Based on this discrimination, the incoming direction of each sound source is determined.

As described above, according to the present invention, the incoming direction of a sound from each sound source is determined in consideration of not only the phase difference spectrum but also the power spectrum. Therefore, it is possible to correctly determine the sound source directions of a plurality of sound sources whose frequency ranges overlap, such as human voice, music instrumental sound, etc., needless to say about the sound source direction of a single sound source.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2006-2284 filed on Jan. 10, 2006 and including specification, claims, drawings and summary. The disclosure of the above Japanese Patent Application is incorporated herein by reference in its entirety.

What is claimed is:

1. A sound source direction determining device for specifying an incoming direction of a sound based on acoustic signals through two channels obtained by two sensors disposed apart from each other by a predetermined distance, the device comprising:
a phase difference spectrum generating unit which obtains a phase difference spectrum of the acoustic signals through the two channels;
a power spectrum generating unit which obtains a power spectrum of at least either one of the acoustic signals through the two channels; and
a sound source direction specifying unit which obtains a sound source direction of each sound source, based on the phase difference spectrum and the power spectrum.

2. The sound source direction determining device according to claim 1,
wherein the sound source direction specifying unit discriminates contributing components of each sound source from the phase difference spectrum, based on the power spectrum.

3. The sound source direction determining device according to claim 1,
wherein the sound source direction specifying unit estimates a harmonic structure of each sound source based on the power spectrum, and discriminates contributing components of each sound source from the phase difference spectrum based on the estimated harmonic structure.

4. The sound source direction determining device according to claim 1,
wherein the sound source direction specifying unit discriminates contributing components of each sound source from the phase difference spectrum, based on a product of a power term, which is a term dependent on the power spectrum, and a phase difference term dependent on the phase difference spectrum.

5. The sound source direction determining device according to claim 1,
wherein the sound source direction specifying unit discriminates contributing components of each sound source from the phase difference spectrum, based on a product of the power spectrum and a phase difference term dependent on the phase difference spectrum.

6. The sound source direction determining device according to claim 1,
wherein sound source direction specifying unit discriminates contributing components of each sound source from the phase difference spectrum, based on a product of components of the power spectrum that take a value larger than a predetermined value and a phase difference term dependent on the phase difference spectrum.

7. The sound source direction determining device according to claim 1,
wherein the power spectrum generating unit obtains the power spectrum of an acoustic signal, which is obtained by either one of the two sensors that is closer to each sound source than the other sensor is.

8. The sound source direction determining device according to claim 1,
wherein the sound source direction specifying unit traces the sound source direction of each sound source, which moves as time goes.

9. The sound source direction determining device according to claim 1,
wherein the sound source direction specifying unit further obtains a number of sound sources.

10. A sound source direction determining method for specifying an incoming direction of a sound based on acoustic signals through two channels obtained by two sensors disposed apart from each other by a predetermined distance, the method comprising:
a first step of obtaining a phase difference spectrum of the acoustic signals through the two channels;
a second step of obtaining a power spectrum of at least either one of the acoustic signals through the two channels; and
a third step of obtaining a sound source direction of each sound source, based on the phase difference spectrum and the power spectrum.

11. A computer-readable recording medium storing a program for controlling a computer to perform sound source direction determination for specifying an incoming direction of a sound based on acoustic signals through two channels obtained by two sensors disposed apart from each other by a predetermined distance,
wherein the sound source direction determination comprises:
a first step of obtaining a phase difference spectrum of the acoustic signals through the two channels;
a second step of obtaining a power spectrum of at least either one of the acoustic signals through the two channels; and
a third step of obtaining a sound source direction of each sound source based on the phase difference spectrum and the power spectrum.
